(19) United States
(12) Patent Application Publication
(10) Pub. No.: US 2025/0061251 A1
(43) Pub. Date: Feb. 20, 2025

(54) MODEL GENERATION DEVICE, MODEL GENERATION METHOD, AND DATA ESTIMATION DEVICE

(71) Applicant: Resonac Corporation, Minato-ku, Tokyo (JP)

(72) Inventor: Ryosuke ARAI, Minato-ku, Tokyo (JP)

(21) Appl. No.: 18/709,071

(22) PCT Filed: Nov. 2, 2022
(86) PCT No.: PCT/JP2022/041088

§ 371 Date: May 10, 2024

(30) Foreign Application Priority Data
Nov. 15, 2021 (JP) 2021-185719

(51) Int. Cl. G06F 30/27

(52) U.S. Cl. CPC G06F 30/27

(57) ABSTRACT

A model generation device generates an estimation model configured by a Gaussian mixture model showing the distribution of data sets with defects in data values related to a sample. The model generation device includes: an acquisition unit that acquires a plurality of data sets; a generation unit that generates an estimation model by calculating a likelihood expressed by the Gaussian mixture model for the plurality of data sets and obtaining parameters that maximize the likelihood by machine learning processing and that calculates a likelihood for each of the plurality of data sets by calculating a likelihood for each sample according to a pattern of the data value defect and calculating a sum of the likelihoods for each of the samples; and an output unit that outputs the estimation model having the obtained parameters.

### TECHNICAL FIELD

One aspect of the present disclosure relates to a model generation device, a model generation method, and a data estimation device.

### BACKGROUND ART

Materials informatics is expected to be a technology that efficiently searches for new materials by analyzing material data using machine learning. The performance of machine learning models, such as accuracy and applicability, largely depends on the amount of data used for learning. Therefore, in order to obtain a large amount of data, efforts have been made to expand data by collecting data from literature and using joint databases of a plurality of organizations. However, in such data sets with different origins, data items are not unified and there are defects in data values in many cases. When a data set has defects in data values, general machine learning methods cannot be applied. Techniques for correcting a data set with defects in data values are known (see, for example, Patent Literatures 1 and 2).

### CITATION LIST

### Patent Literature

Patent Literature 1: Japanese Unexamined Patent Publication No. 2020-154828
Patent Literature 2: Japanese Unexamined Patent Publication No. 2019-125110

### SUMMARY OF INVENTION

### Technical Problem

When a data set in which defects in data values have been corrected is used for machine learning, if the correction method is not appropriate, the analysis result is adversely affected. The trial and error and effort required to correct defects using an appropriate method are very complicated. In addition, in the analysis using a decision tree-based method, learning can be performed without defect correction, but decision trees have low prediction performance by extrapolation.

Therefore, the present invention has been made in view of the above problems, and it is an object of the present invention to provide an analysis method that has high prediction performance by extrapolation and can use a data set with defects in data values without requiring data value correction.

### Solution to Problem

A model generation device according to one aspect of the present disclosure is a model generation device for generating an estimation model configured by a Gaussian mixture model showing a distribution of a data set related to a sample. The data set includes data values corresponding to a plurality of data items, and at least one of a plurality of the data sets has a defect in a data value corresponding to at least one of the plurality of data items. The model generation device includes: an acquisition unit that acquires the plurality of data sets; a generation unit that generates the estimation model by calculating a likelihood expressed by the Gaussian mixture model for the plurality of data sets and obtaining parameters that maximize the likelihood by machine learning processing and that calculates a likelihood for each of the plurality of data sets by calculating a likelihood for each sample according to a pattern of the data value defect and calculating a sum of the likelihoods for each of the samples; and an output unit that outputs the estimation model having the parameters obtained by the generation unit.

A model generation method according to one aspect of the present disclosure is a model generation method in a model generation device for generating an estimation model configured by a Gaussian mixture model showing a distribution of a data set related to a sample. The data set includes data values corresponding to a plurality of data items, and at least one of a plurality of the data sets has a defect in a data value corresponding to at least one of the plurality of data items. The model generation method includes: an acquisition step for acquiring the plurality of data sets; a generation step for generating the estimation model by calculating a likelihood expressed by the Gaussian mixture model for the plurality of data sets and obtaining parameters that maximize the likelihood by machine learning processing and for calculating a likelihood for each of the plurality of data sets by calculating a likelihood for each sample according to a pattern of the data value defect and calculating a sum of the likelihoods for each of the samples; and an output step for outputting the estimation model having the parameters obtained in the generation step.

According to this aspect, an estimation model configured by the Gaussian mixture model is generated by machine learning using a data set group including data sets with defects in data values as learning data. Therefore, it is possible to acquire an estimation model with high prediction performance by extrapolation. In addition, it is possible to calculate the likelihood for the data set group by calculating the likelihood for each sample according to the pattern of data value defects and calculating the sum of the likelihoods for each of the samples. Therefore, even if the data set has defects in data values, it is possible to generate an estimation model by obtaining parameters that maximize the likelihood for the data set group by machine learning processing without correcting the defects.

In the model generation device according to another aspect, the sample may be a composition, and the plurality of data items may include at least one of a parameter indicating a physical property of the composition and a parameter acquired during production of the composition.

According to this aspect, it is possible to generate an estimation model, which shows the distribution of parameters such as physical properties related to the composition, using the Gaussian mixture model.

In the model generation device according to still another aspect, the generation unit may calculate a likelihood for each of the plurality of data sets by dividing the data sets into a plurality of groups for each pattern of the data value defect, calculating the likelihood for each group, and calculating a sum of the likelihoods for each of the groups.

According to this aspect, it is possible to calculate the likelihood for each group by dividing the data sets into groups for each pattern of data value defects. Then, by calculating the sum of the likelihoods for each of the groups, it is possible to calculate the likelihood for the data set group.

In the model generation device according to still another aspect, the generation unit may calculate a log likelihood for each of the plurality of data sets by calculating a log likelihood for each sample according to the pattern of the data value defect and calculating a sum of the log likelihoods for each of the samples.

According to this aspect, the likelihood of a data set group that is maximized in the learning process using the Gaussian mixture model can be calculated as a log likelihood.

In the model generation device according to still another aspect, the plurality of data items may include an explanatory variable and an objective variable related to the sample.

According to this aspect, the distribution of samples indicated by a variable group including the explanatory variable and the objective variable can be expressed by the Gaussian mixture model.

A data estimation device according to one aspect of the present disclosure is a data estimation device for estimating a data value of a data item related to a sample using an estimation model generated by machine learning. The estimation model is configured by a Gaussian mixture model showing a distribution of a data set related to the sample. A training data set, which is a data set related to the sample for generating the estimation model, includes data values corresponding to a plurality of data items, and at least one of a plurality of the training data sets has a defect in a data value corresponding to at least one of the plurality of data items. The estimation model is generated by calculating a likelihood expressed by the Gaussian mixture model for the plurality of training data sets and obtaining parameters that maximize the likelihood by machine learning processing, and a likelihood for each of the plurality of training data sets is calculated by calculating a likelihood for each sample according to a pattern of the data value defect and calculating a sum of the likelihoods for each of the samples. The data estimation device includes: an input unit that inputs data values or a distribution of data values of a first data item group, which is one or more data items among a plurality of data items forming the data set related to the sample, to the estimation model; an estimation unit that estimates data values of a second data item group, which is data items other than the first data item group among the plurality of data items, by acquiring a distribution of the data values of the second data item group that is output from the estimation model; and a data output unit that outputs the distribution of the data values of the second data item group.

According to this aspect, an estimation model based on the Gaussian mixture model that is generated by machine learning processing with no need to correct defects is used to estimate data values using the data set group including data sets with defects in data values as learning data. Then, by inputting the data values of the first data item group to the estimation model, it is possible to acquire the distribution of the data values of the second data item group output from the estimation model.

### Advantageous Effects of Invention

According to one aspect of the present disclosure, it is possible to provide an analysis method that has high prediction performance by extrapolation and can use a data set with defects in data values without requiring data value correction.

### BRIEF DESCRIPTION OF DRAWINGS

FIG. 1 is a block diagram showing an example of the functional configuration of a model generation device according to an embodiment.

FIG. 2 is a block diagram showing an example of the functional configuration of a data estimation device according to an embodiment.

FIG. 3 is a hardware block diagram of the model generation device and the data estimation device according to the embodiment.

FIG. 4 is a diagram showing an example of a data set group including a plurality of data sets.

FIG. 5 is a flowchart showing the processing details of a model generation method in the model generation device.

FIG. 6 is a flowchart showing the processing details of likelihood calculation processing.

FIG. 7 is a flowchart showing the processing details of a data estimation method in the data estimation device.

FIG. 8 is a diagram showing the configuration of a model generation program.

FIG. 9 is a diagram showing the configuration of a data estimation program.

### DESCRIPTION OF EMBODIMENTS

Hereinafter, an embodiment of the present invention will be described in detail with reference to the accompanying diagrams. In addition, in the description of the diagrams, the same or equivalent elements are denoted by the same reference numerals, and the repeated description thereof will be omitted.

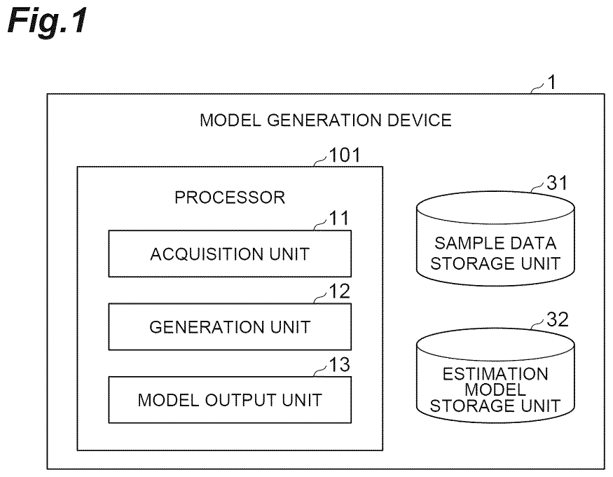

FIG. 1 is a block diagram showing an example of the functional configuration of a model generation device according to an embodiment. A model generation device 1 is a device that generates an estimation model configured by a Gaussian mixture model showing the distribution of a data set related to a sample.

As shown in FIG. 1, the model generation device 1 may include functional units formed in a processor 101, a sample data storage unit 31, and an estimation model storage unit 32. Functionally, the model generation device 1 includes an acquisition unit 11, a generation unit 12, and a model output unit 13. Each of these functional units 11 to 13 may be formed in one device, or may be formed in a distributed manner in a plurality of devices.

Each of the functional units 11 to 13 is formed so as to be able to access the sample data storage unit 31 and the estimation model storage unit 32. The sample data storage unit 31 and the estimation model storage unit 32 may be formed inside the model generation device 1 as shown in FIG. 1, or may be formed outside the model generation device 1, that is, in another device accessible from the model generation device 1. Each of the functional units 11 to 13 and each of the storage units 31 and 32 will be described in detail later.

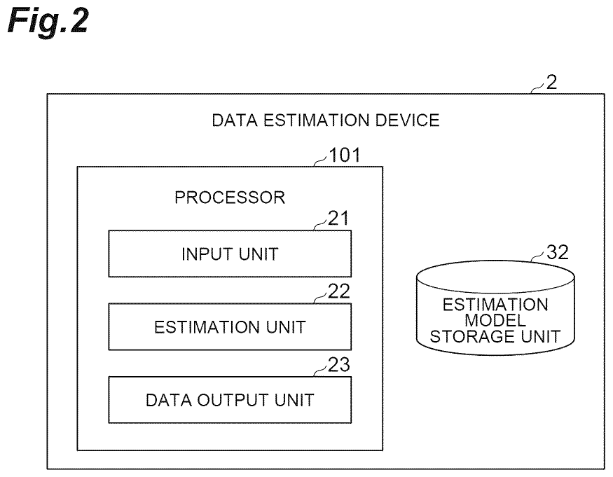

FIG. 2 is a block diagram showing an example of the functional configuration of a data estimation device according to an embodiment. A data estimation device 2 is a device that predicts the product quality of a plurality of types of products manufactured in a plant by using an estimation model constructed by machine learning.

As shown in FIG. 2, the data estimation device 2 can include functional units formed in a processor 101 and an estimation model storage unit 32. Functionally, the data estimation device 2 includes an input unit 21, an estimation unit 22, and a data output unit 23. Each of these functional units 21 to 23 may be formed in one device, or may be formed in a distributed manner in a plurality of devices.

Each of the functional units 21 to 23 is configured so as to be able to access the estimation model storage unit 32. The estimation model storage unit 32 may be formed inside the data estimation device 2 as shown in FIG. 2, or may be formed outside the data estimation device 2, that is, in another device accessible from the data estimation device 2. In addition, the estimation model storage unit 32 shown in FIG. 2 may be formed as the same storage unit as the storage unit shown in FIG. 1. Each of the functional units 21 to 23 will be described in detail later.

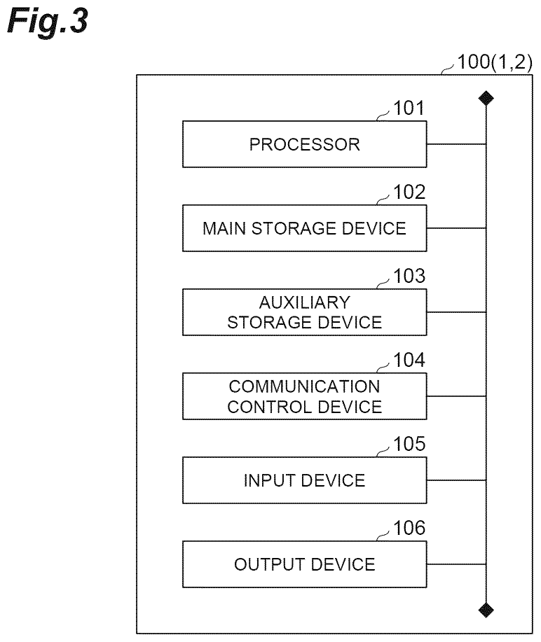

FIG. 3 is a diagram showing an example of the hardware configuration of a computer 100 that forms the model generation device 1 and the data estimation device 2 according to the embodiment. That is, the computer 100 can form the model generation device 1 and the data estimation device 2.

As an example, the computer 100 includes the processor 101, a main storage device 102, an auxiliary storage device 103, and a communication control device 104 as hardware components. The computer 100 forming the model generation device 1 and the data estimation device 2 may further include an input device 105, such as a keyboard, a touch panel, and a mouse that are input devices, and an output device 106 such as a display.

The processor 101 is a calculation device that executes an operating system and application programs. Examples of the processor include a CPU (Central Processing Unit) and a GPU (Graphics Processing Unit), but the type of the processor 101 is not limited to these. For example, the processor 101 may be a combination of a sensor and a dedicated circuit. The dedicated circuit may be a programmable circuit such as an FPGA (Field-Programmable Gate Array), or may be another type of circuit.

The main storage device 102 is a device that stores programs for realizing the model generation device 1 and the like, calculation results output from the processor 101, and the like. The main storage device 102 includes, for example, at least one of a ROM (Read Only Memory) and a RAM (Random Access Memory).

The auxiliary storage device 103 is generally a device that can store a larger amount of data than the main storage device 102. For example, the auxiliary storage device 103 is formed by a nonvolatile storage medium such as a hard disk or a flash memory. The auxiliary storage device 103 stores a model generation program P1 or a data estimation program P2 and various kinds of data for causing the computer 100 to function as the model generation device 1 or the data estimation device 2.

The communication control device 104 is a device that performs data communication with other computers through a communication network. The communication control device 104 is, for example, a network card or a wireless communication module.

Each functional element of the model generation device 1 and the data estimation device 2 is realized by loading the corresponding model generation program P1 and data estimation program P2 onto the processor 101 or the main storage device 102 and causing the processor 101 to execute the programs. The model generation program P1 and the data estimation program P2 include codes for realizing each functional element of the corresponding server. The processor 101 operates the communication control device 104 according to the model generation program P1 and the data estimation program P2 to read and write data from and into the main storage device 102 or the auxiliary storage device 103. Through such processing, each functional element of the corresponding server is realized.

The model generation program P1 and the data estimation program P2 may be provided after being fixedly recorded on a tangible recording medium, such as a CD-ROM, a DVD-ROM, or a semiconductor memory. Alternatively, at least one of these programs may be provided through a communication network as a data signal superimposed on a carrier wave.

Referring again to FIG. 1, each functional unit of the model generation device 1 will be described. The acquisition unit 11 acquires the plurality of data sets. Specifically, the acquisition unit 11 acquires a data set group stored in the sample data storage unit 31, for example.

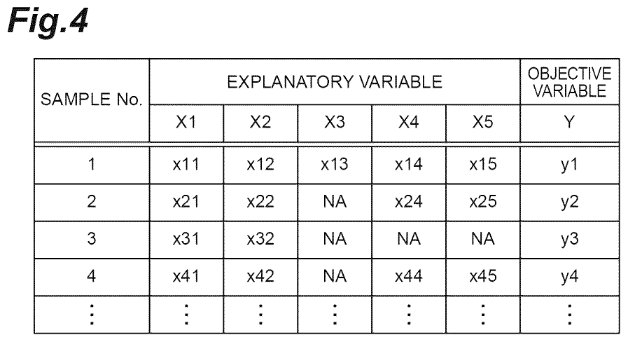

FIG. 4 is a diagram showing an example of the configuration of a data set group stored in the sample data storage unit 31. As shown in FIG. 4, each data set includes data values corresponding to a plurality of data items associated with sample No. to identify a sample. The data items are explanatory variables (X1 to X5) and an objective variable (Y) related to a sample.

The sample is, for example, a composition. The data item of the sample of the composition may include, for example, at least one of a parameter indicating the physical property of the composition and a parameter obtained during production of the composition.

In the field of materials informatics to which the model generation device 1 according to the present embodiment can be applied, in order to improve the performance of machine learning models, such as accuracy and applicability, a large amount of data sets are collected for use in learning. Data sets are collected, for example, by collecting data from literature and using joint databases of a plurality of organizations. In such data sets with different origins, data items are not unified and there are defects in data values in many cases.

As shown in FIG. 4, at least one data set in a data set group used for the training of the estimation model has a defect in a data value corresponding to at least one of a plurality of data items. For example, a data set of sample No. 1 does not have any defect in data values. A data set of sample No. 2 has a defect in a data value of a data item X3 because the data value of the data item X3 is “NA (Not Available)”.

A data set of sample No. 3 has a defect in data values of data items X3, X4, and X5 because the data values of the data items X3, X4, and X5 are “NA”. A data set of sample No. 4 has a defect in the data value of the data item X3 because the data value of the data item X3 is “NA”, and has the same defect pattern as the sample No. 2.

The generation unit 12 generates an estimation model by calculating a likelihood expressed by the Gaussian mixture model for a plurality of data sets and obtaining parameters that maximize the likelihood using machine learning processing. Specifically, the generation unit 12 calculates likelihoods for a plurality of data sets by calculating a likelihood for each sample according to the pattern of data value defects and calculating the sum of the likelihoods for each of the samples. Details of the generation of an estimation model will be described later.

The model output unit 13 outputs an estimation model having parameters obtained by the generation unit 12. Specifically, the model output unit 13 stores the generated estimation model in the estimation model storage unit 32, for example.

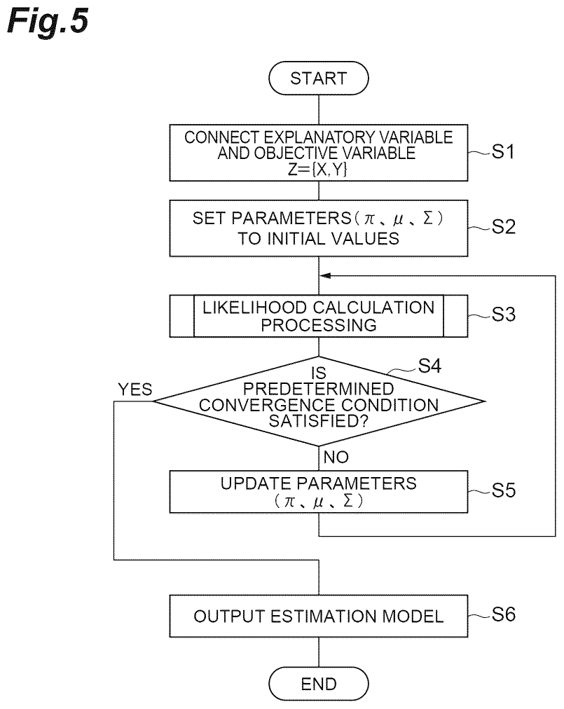

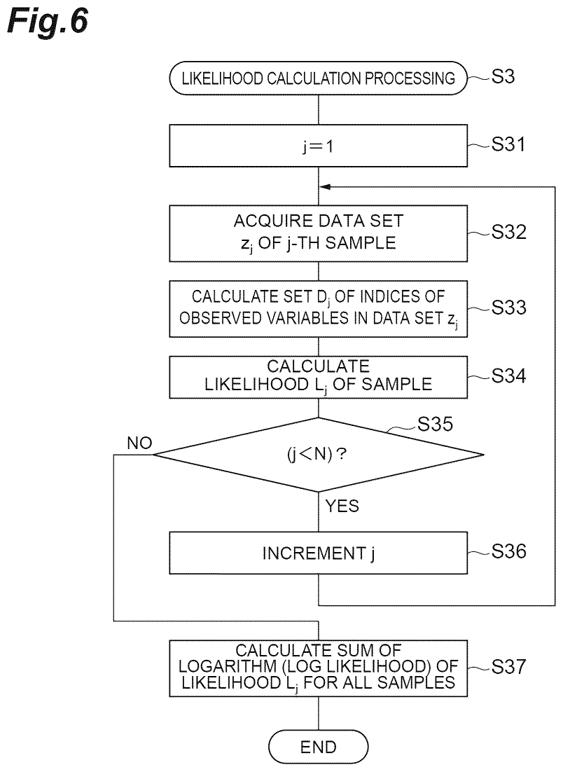

Next, the generation and output of an estimation model will be described in detail with reference to FIGS. 5 and 6. FIG. 5 is a flowchart showing the processing details of a model generation method in the model generation device 1. FIG. 6 is a flowchart showing the processing details of likelihood calculation processing.

Prior to explaining the processing details of the flowchart, the equation for calculating the likelihood using the Gaussian mixture model used during the processing will be described. First, the equation for calculating the likelihood using a general Gaussian mixture model is shown below (Equation (1)).

$$\begin{matrix}[ Formula 1 ] & \\ log L ( X \vert π , μ , \sum ) = {\sum }_{n = 1}^{N} log \{ {\sum }_{m = 1}^{M} {π}_{m} N ( {x}_{j} \vert {μ}_{m} , {\sum }_{m} ) \} & ( 1 )\end{matrix}$$

In Equation (1), L is a likelihood, X is a data value, π is a weight, μ is a mean vector, and Σ is a variance-covariance matrix. In the Gaussian mixture model, parameters (π, μ, Σ) that maximize the log likelihood log L are obtained.

Here, when the data value X of the data set has a defect, likelihood calculation using Equation (1) is not possible. Therefore, in the present embodiment, in order to enable the calculation of likelihood for a data set with defects in data values, the likelihood (log likelihood) is calculated using Equation (2).

$$\begin{matrix}[ Formula 2 ] & \\ log L ( Z \vert π , μ , \sum ) = {\sum }_{n = 1}^{N} log \{ {\sum }_{m = 1}^{M} {π}_{m} N ( {x}_{n} \vert {μ}_{m}^{( n )} , {\sum }_{m}^{( n )} ) \} & ( 2 )\end{matrix}$$

Here, the data and parameters on the right side of Equation (2) are expressed by Equations (3) to (5) below.

$$\begin{matrix}[ Formula 3 ] & \\ {z}_{n}^{′} = {z}_{n , j ∈ {D}_{n}} & ( 3 )\end{matrix}$$

$$\begin{matrix}[ Formula 4 ] & \\ {λ}_{m}^{( n )} = {μ}_{m , j ∈ {D}_{n}} & ( 4 )\end{matrix}$$

$$\begin{matrix}[ Formula 5 ] & \\ {\sum }_{m}^{( n )} = {\sum }_{m , j ∈ {D}_{n} , k , ∈ {D}_{n}} & ( 5 )\end{matrix}$$

In Equation (2), Z indicates data (Z={X, Y}) in which the explanatory variable X and the objective variable Y are connected. In addition, in Equation (2), the parameters (π, μ, Σ) indicate a mixing coefficient of the normal distribution, a mean vector of each normal distribution, and a variance-covariance matrix of each normal distribution, respectively, and are defined as follows.

$$π = ( {π}_{1} , {π}_{2} , … , {π}_{M} )$$

$$μ = ( {μ}_{1} , {μ}_{2} , … , {μ}_{M} )$$

$$\sum = ( {\sum }_{1} , {\sum }_{2} , … , {\sum }_{M} )$$

Zₙ indicates the n-th sample of the data Z, and the data Z is expressed as in Equation (6).

$$\begin{matrix}[ Formula 6 ] & \\ Z = {\{ {z}_{1} , {z}_{2} , … , {z}_{n} \}}^{T} & ( 6 )\end{matrix}$$

Dₙ is a set of indices of observed variables in the n-th sample. Equation (3) represents a vector of components of Zₙ that do not have defects in data values.

Equation (4) represents an average vector using only components related to data values (data values with no defects) acquired in the n-th sample among the average vectors in the m-th normal distribution.

Equation (5) represents a variance-covariance matrix using only components related to data values (data values with no defects) acquired in the n-th sample among the variance-covariance matrices in the m-th normal distribution. The variables j and k each indicate an index in the dimensional direction of each piece of data. The variable j in the average vector μₘ in Equation (4) indicates an index in the column direction. The variables j and k in the variance-covariance matrix Σₘ in Equation (5) indicate indices in the row direction and the column direction, respectively. In addition, the variable M in Equation (2) indicates the number of assumed Gaussian distributions.

In addition, in order to explain the calculation of the log likelihood, the likelihood Ln of the n-th sample on the right side of Equation (2) is expressed as in Equation (7) below.

$$\begin{matrix}[ Formula 7 ] & \\ {L}_{n} = {\sum }_{m = 1}^{M} {π}_{m} N ( {z}_{n}^{′} \vert {μ}_{m}^{( n )} , {\sum }_{m}^{( n )} ) & ( 7 )\end{matrix}$$

The estimation model generation processing will be described with reference to FIG. 5. In step S1, the generation unit 12 generates the data Z (Z={X, Y}) in which the explanatory variable X and the objective variable Y are connected.

In step S2, the generation unit 12 sets the parameters (π, μ, Σ) in Equation (2) to initial values before optimization (maximization of likelihood).

In step S3, the generation unit 12 performs likelihood calculation processing. The likelihood calculation processing will be described in detail with reference to FIG. 6. The generation unit 12 calculates a likelihood for a data set group (a plurality of data sets) by calculating a likelihood for each sample (for each data set) according to the pattern of data value defects and calculating the sum of the likelihoods for each of the samples.

In step S31, the generation unit 12 sets a variable n corresponding to sample No to 1.

In step S32, the generation unit 12 acquires a data set Zₙ of the n-th sample.

In step S33, the generation unit 12 calculates a set Dₙ of indices of observed variables in the data set Zₙ. The observed variable is a data item with no defects in data value. Specifically, the generation unit 12 acquires indices of data values with no defects among the data values of the n-th sample zₙ=(Zₙ₁, Zₙ₂, . . . , Z_{nK}).

In step S34, the generation unit 12 calculates the likelihood Ln (Equation (7)) of the n-th sample. The generation unit 12 calculates the likelihood for each sample (for each data set) according to the pattern of data value defects based on the procedure shown in steps S32 to S34.

In step S35, the generation unit 12 determines whether or not the variable n is less than the number of samples (the number of data sets in the data set group) N. That is, in step S35, it is determined whether or not the calculation of the likelihood Ln for all samples has been completed. When it is determined that the variable n is less than the number of samples N, the process proceeds to step S36.

In step S36, the generation unit 12 increments the variable n. Then, the processing of steps S32 to S35 is repeated.

On the other hand, when it is not determined in step S35 that the variable n is less than the number of samples N, the process proceeds to step S37.

In step S37, the sum (the right side of Equation (2)) of the logarithms (log likelihoods) of the likelihoods Ln for all samples is calculated.

Referring again to FIG. 5, in step S4, the generation unit 12 determines whether or not the calculated log likelihood related to the data set group satisfies a predetermined convergence condition. The predetermined convergence condition may be, for example, that the difference between the log likelihood calculated this time and the log likelihood calculated last time is equal to or less than a predetermined value. When it is determined that the predetermined convergence condition is satisfied, the parameters (π, μ, Σ) are determined, and the process proceeds to step S6. On the other hand, when it is not determined that the predetermined convergence condition is satisfied, the process proceeds to step S5.

In step S5, the generation unit 12 updates the parameters (π, μ, Σ) based on the calculated likelihood. Then, the processing of steps S3 and S4 is repeated so that the likelihood is maximized.

In step S6, the model output unit 13 outputs an estimation model having the determined parameters (π, μ, Σ). In addition, the processing described with reference to the flowcharts of FIGS. 5 and 6 is based on a so-called iterative method. The processing for generating an estimation model by determining parameters is not limited to the iterative method, and may be, for example, a method such as an EM algorithm or a method of steepest descent.

The estimation model whose parameters have been determined through such learning processing can be read or referenced by a computer, and can be regarded as a program that causes the computer to perform predetermined processing and the computer to realize a predetermined function.

That is, the trained estimation model according to the present embodiment is used in a computer including a processor and a memory. Specifically, a computer processor operates to perform a calculation, which is based on the trained parameters and the like, on input data according to an instruction from the trained estimation model stored in the memory and output the calculation result.

In addition, the generation unit 12 may calculate the likelihood (log likelihood) for a data set group by dividing data sets into a plurality of groups for each pattern of data value defects, calculating the likelihood (log likelihood) for each group, and calculating the sum of the likelihoods of the groups.

In this case, a set Di (step S33) of indices of observed variables related to data sets belonging to the same group is the same. For this reason, in calculating the sum of log likelihoods related to data sets belonging to one group, it is not necessary to calculate the set Dₙ of indices of observed variables for each data set. Therefore, the likelihood calculation processing becomes easy.

Next, functional units of the data estimation device 2 will be described with reference to FIG. 2. Each functional unit of the data estimation device 2 acquires and refers to, for example, an estimation model stored in the estimation model storage unit 32 and estimates the data value of a data item related to a sample.

The input unit 21 inputs data values or the distribution of data values of a first data item group that is one or more data items, among a plurality of data items forming a data set related to the sample, to the estimation model.

The data set related to the sample has a similar structure to the data set described with reference to FIG. 4. The input unit 21 inputs data values or the distribution of data values of the explanatory variable X to the estimation model, using the explanatory variable X as a first data item among the data items forming the data set.

The estimation unit 22 estimates data values of a second data item group, which is data items other than the first data item group among the plurality of data items, by acquiring the distribution of the data values of the second data item group that is output from the estimation model. Specifically, the estimation unit 22 acquires the distribution of data values of the objective variable Y that is output from the estimation model in response to the input of the explanatory variable X by the input unit 21.

The data output unit 23 outputs the distribution of data values of the second data item group. Specifically, the data output unit 23 outputs the distribution of the objective variable Y estimated by the estimation unit 22.

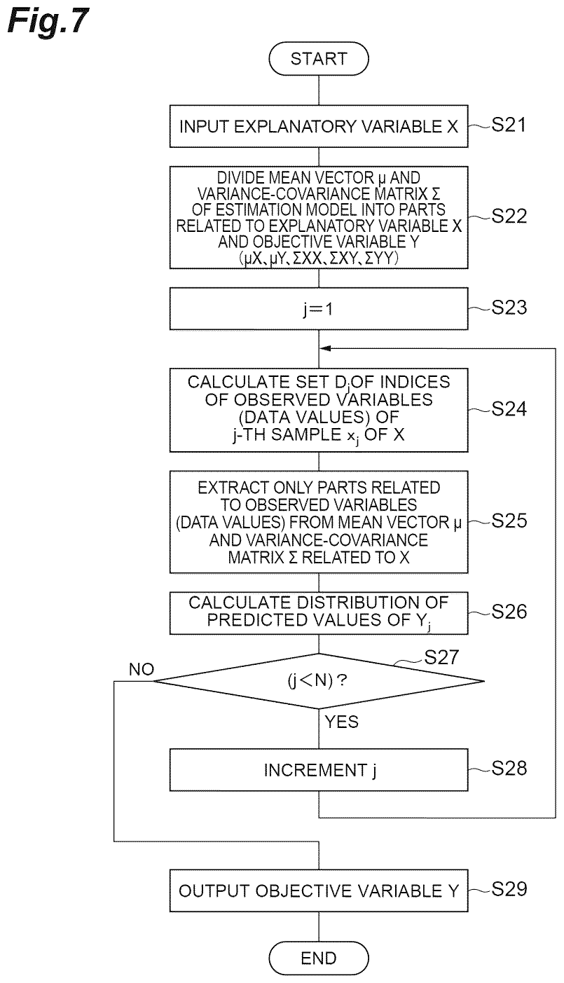

Estimation of data values using the estimation model and output of data values will be described in detail with reference to FIG. 7.

In step S21, the input unit 21 inputs the explanatory variable X in a data set related to a sample to be estimated to the estimation model.

In step S22, the estimation unit 22 divides the mean vector u and the variance-covariance matrix 2 of the estimation model configured by a Gaussian mixture model into parts related to the explanatory variable X and the objective variable Υ (μ_{X}, μ_{Y}, Σ_{XX}, Σ_{XY}, Σ_{YY}).

In step S23, the estimation unit 22 sets the variable n to 1. In step S24, the estimation unit 22 calculates a set Dₙ of indices of observed variables (data values) with the explanatory variable X of the n-th sample as Xₙ.

In step S25, the estimation unit 22 extracts only parts related to the observed variables from the mean vector u and the variance-covariance matrix 2 related to the explanatory variable X.

In step S26, the estimation unit 22 calculates the distribution of predicted values of Yₙ by using the estimation model.

In step S27, the estimation unit 22 determines whether or not the variable n is less than the number of samples N. When it is determined that the variable n is less than N, the process proceeds to step S28. On the other hand, when it is not determined that the variable n is less than N, that is, when the variable n is N, the process proceeds to step S29.

In step S28, the estimation unit 22 increments the variable n. Then, the processing of steps S24 to S27 is repeated.

In step S29, the objective variable Y is output.

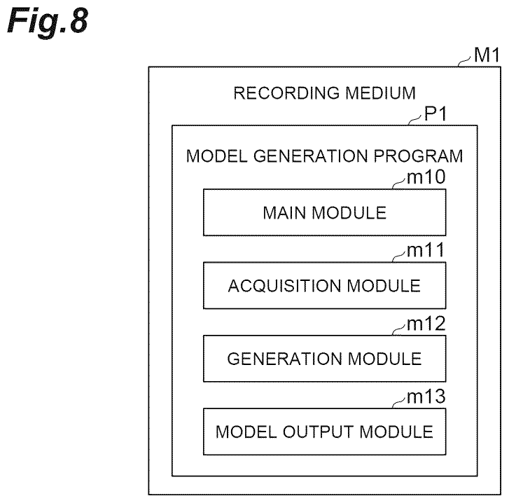

Next, a model generation program for causing a computer to function as the model generation device 1 according to the present embodiment will be described. FIG. 8 is a diagram showing the configuration of the model generation program P1.

The model generation program P1 includes a main module m10 that performs overall control of model generation processing in the model generation device 1, an acquisition module m11, a generation module m12, and a model output module m13. Then, the functions for the acquisition unit 11, the generation unit 12, and the model output unit 13 are realized by the modules m11 to m13, respectively.

In addition, the model generation program P1 may be transmitted through a transmission medium such as a communication line, or may be stored in a recording medium M1 as shown in FIG. 8.

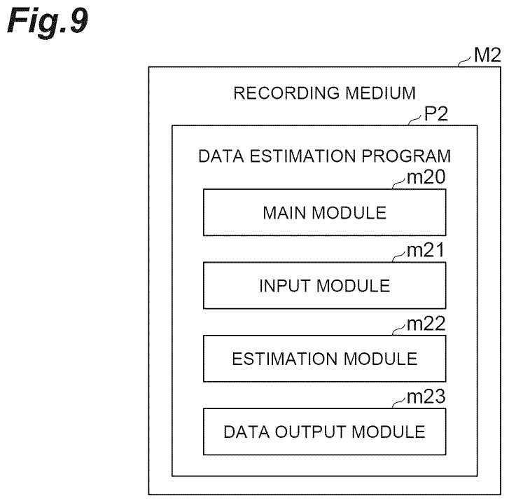

Next, a data estimation program for causing a computer to function as the data estimation device 2 according to the present embodiment will be described. FIG. 9 is a diagram showing the configuration of the data estimation program P2.

The data estimation program P2 includes a main module m20 that performs overall control of data estimation processing in the data estimation device 2, an input module m21, an estimation module m22, and a data output module m23. Then, the functions for the input unit 21, the estimation unit 22, and the data output unit 23 are realized by the modules m21 to m23, respectively.

In addition, the data estimation program P2 may be transmitted through a transmission medium such as a communication line, or may be stored in a recording medium M2 as shown in FIG. 9.

According to the model generation device 1, the model generation method, and the model generation program P1 of the present embodiment described above, the estimation model configured by a Gaussian mixture model is generated by machine learning using a data set group including data sets with defects in data values as learning data. Therefore, it is possible to obtain an estimation model with high prediction performance by extrapolation. In addition, it is possible to calculate the likelihood for a data set group by calculating the likelihood for each sample according to the pattern of data value defects and calculating the sum of the likelihoods for the samples. Therefore, even if a data set has defects in data values, an estimation model can be generated by obtaining the parameters, which maximize the likelihood for the data set group, by machine learning processing without correcting the defects.

In addition, according to the data estimation device 2, the data estimation method, and the data estimation program P2 of the present embodiment, an estimation model based on the Gaussian mixture model that is generated by machine learning processing with no need to correct defects is used to estimate data values using a data set group including data sets with defects in data values as learning data. Then, by inputting the data values of the first data item group to the estimation model, it is possible to acquire the distribution of the data values of the second data item group output from the estimation model.

Up to now, the present invention has been described in detail through the embodiment thereof. However, the present invention is not limited to the embodiment described above. The present invention can be modified in various ways without departing from the gist thereof.

### REFERENCE SIGNS LIST

1: model generation device, 2: data estimation device, 11: acquisition unit, 12: generation unit, 13: model output unit, 21: input unit, 22: estimation unit, 23: data output unit, 31: sample data storage unit, 32: estimation model storage unit, M1: recording medium, m11: acquisition module, m12: generation module, m13: model output module, M2: recording medium, m21: input module, m22: estimation module, m23: data output module, P1: model generation program, P2: data estimation program.

1. A model generation device for generating an estimation model configured by a Gaussian mixture model showing a distribution of a data set related to a sample,
wherein the data set includes data values corresponding to a plurality of data items, and at least one of a plurality of the data sets has a defect in a data value corresponding to at least one of the plurality of data items, and
the model generation device comprises:
an acquisition unit that acquires the plurality of data sets;
a generation unit that generates the estimation model by calculating a likelihood expressed by the Gaussian mixture model for the plurality of data sets and obtaining parameters that maximize the likelihood by machine learning processing and that calculates a likelihood for each of the plurality of data sets by calculating a likelihood for each sample according to a pattern of the data value defect and calculating a sum of the likelihoods for each of the samples; and
an output unit that outputs the estimation model having the parameters obtained by the generation unit.

2. The model generation device according to claim 1,
wherein the sample is a composition, and
the plurality of data items include at least one of a parameter indicating a physical property of the composition and a parameter acquired during production of the composition.

3. The model generation device according to claim 1 or 2,
wherein the generation unit calculates a likelihood for each of the plurality of data sets by dividing the data sets into a plurality of groups for each pattern of the data value defect, calculating the likelihood for each group, and calculating a sum of the likelihoods for each of the groups.

4. The model generation device according to claim 1,
wherein the generation unit calculates a log likelihood for each of the plurality of data sets by calculating a log likelihood for each sample according to the pattern of the data value defect and calculating a sum of the log likelihoods for each of the samples.

5. The model generation device according to claim 1,
wherein the plurality of data items include an explanatory variable and an objective variable related to the sample.

6. A model generation method in a model generation device for generating an estimation model configured by a Gaussian mixture model showing a distribution of a data set related to a sample,
wherein the data set includes data values corresponding to a plurality of data items, and at least one of a plurality of the data sets has a defect in a data value corresponding to at least one of the plurality of data items, and
the model generation method comprises:
an acquisition step for acquiring the plurality of data sets;
a generation step for generating the estimation model by calculating a likelihood expressed by the Gaussian mixture model for the plurality of data sets and obtaining parameters that maximize the likelihood by machine learning processing and for calculating a likelihood for each of the plurality of data sets by calculating a likelihood for each sample according to a pattern of the data value defect and calculating a sum of the likelihoods for each of the samples; and
an output step for outputting the estimation model having the parameters obtained in the generation step.

7. A data estimation device for estimating a data value of a data item related to a sample using an estimation model generated by machine learning,
wherein the estimation model is configured by a Gaussian mixture model showing a distribution of a data set related to the sample,
a training data set, which is a data set related to the sample for generating the estimation model, includes data values corresponding to a plurality of data items, and at least one of a plurality of the training data sets has a defect in a data value corresponding to at least one of the plurality of data items,
the estimation model is generated by calculating a likelihood expressed by the Gaussian mixture model for the plurality of training data sets and obtaining parameters that maximize the likelihood by machine learning processing, and a likelihood for each of the plurality of training data sets is calculated by calculating a likelihood for each sample according to a pattern of the data value defect and calculating a sum of the likelihoods for each of the samples, and
the data estimation device comprises:
an input unit that inputs data values or a distribution of data values of a first data item group, which is one or more data items among a plurality of data items forming the data set related to the sample, to the estimation model;
an estimation unit that estimates data values of a second data item group, which is data items other than the first data item group among the plurality of data items, by acquiring a distribution of the data values of the second data item group that is output from the estimation model; and
a data output unit that outputs the distribution of the data values of the second data item group.
